(19) United States
(12) Patent Application Publication
(10) Pub. No.: US 2013/0146937 A1
(43) Pub. Date: Jun. 13, 2013

(54) MOUNTING SUBSTRATE, LIGHT-EMITTING DEVICE, AND LAMP

(71) Applicants: Koji Omura, Osaka (JP); Atsushi Motoya, Shiga (JP); Yoshio Manabe, Osaka (JP)

(72) Inventors: Koji Omura, Osaka (JP); Atsushi Motoya, Shiga (JP); Yoshio Manabe, Osaka (JP)

(73) Assignee: PANASONIC CORPORATION, Osaka (JP)

(21) Appl. No.: 13/817,855

(22) PCT Filed: Dec. 20, 2011
(86) PCT No.: PCT/JP2011/007136

§ 371 Date: Feb. 20, 2013

(30) Foreign Application Priority Data
Jan. 13, 2011 (JP) 2011-005205

(51) Int. Cl. H01L 33/62

(52) U.S. Cl. CPC H01L 33/62
USPC 257/99

(57) ABSTRACT

A substrate having a mounting surface on which an LED is mounted, including: a conductive member provided on the mounting surface and including an electrode and wiring which are electrically connected to the LED; a fitting portion to which a metal body is fitted; and a discharge-reducing portion provided between the conductive member and the fitting portion and having a face tilted with respect to a surface of the mounting substrate, thereby increasing a creeping distance between the conductive member and the fitting portion compared to the case where the discharge-reducing portion is not provided.

### TECHNICAL FIELD

The present invention relates to mounting substrates on which semiconductor light-emitting elements are mounted, light-emitting devices which use the semiconductor light-emitting elements, and lamps which include the light-emitting devices.

### BACKGROUND ART

In recent years, semiconductor light-emitting elements such as light emitting diodes (LEDs), which have high efficiency and long service life, have been expected as a new light source for various lamps, and research and development have therefore been carried out on LED lamps, which use LEDs as a light source.

Such LED lamps include straight-tube-shaped LED lamps (LED tube lamps) and bulb-shaped LED lamps (LED bulb lamps). Each of these lamps includes an LED module (a light-emitting module) in which a plurality of LEDs are mounted on a substrate.

It is known that the light output from the LEDs is reduced and their service life is shortened as their temperature increases. Thus, for example, in order to improve the heat radiation properties of the LED module, a metal substrate coated with an insulator film is sometimes used as a substrate of the LED module.

In this case, the level of dielectric strength voltage between conductive members, such as electrodes, on the substrate and the metal under the insulator film needs to be ensured.

Accordingly, a technique for improving the level of dielectric strength voltage in an LED module which includes a metal substrate has been disclosed (see Patent Literature (PTL) 1, for example).

The technique disclosed in PTL 1 aims to ensure a predetermined level of dielectric strength voltage by forming multiple insulating layers all over the top surface of a metallic base material and providing wiring patterns and light-emitting elements on the multiple insulating layers.

### CITATION LIST

### Patent Literature

### [PTL 1]

Japanese Unexamined Patent Application Publication No. 2010-135749

### SUMMARY OF INVENTION

### Technical Problem

However, with the above-described conventional technique, insulator films are formed in layers on the metallic base material to improve the level of dielectric strength voltage, with the result that the heat radiation properties will necessarily be degraded.

To deal with this, in some LED modules, a ceramic substrate, a glass substrate, or the like is adopted as the substrate of the LED module, and a metal body which plays a role as a heat radiator is fitted to the under side of the substrate.

In this case, since the substrate is made of an insulting material, the problem of dielectric strength voltage does not occur between the substrate and conductive members on the substrate, and since the metal body is in contact with the substrate, a certain level of heat radiation is ensured.

However, in this case, there is a possibility of causing creeping discharge, which means electric discharge of such a type that an electric current flows along a surface of the substrate which is an insulator, when an excessive potential difference occurs between the conductive members on the substrate and the metal body on the under side of the substrate.

For example, static electricity may cause such an excessive potential difference in the LED module.

As a measure to prevent the occurrence of such creeping discharge, the size of the substrate (the vertical and horizontal lengths of the mounting surface) is increased, for example. In other words, the measure is to expand the region around elements such as LEDs and electrodes. This makes it possible to increase the creeping distance between the conductive members and the metal body, with the result that the occurrence of creeping discharge is reduced.

However, increasing the size of the substrate impedes the miniaturization of an LED lamp and becomes a factor of lowering the applicability of the substrate to various types of the LED lamp, for example, which is therefore far from a preferable measure.

In view of the above conventional problems, the present invention aims to provide a mounting substrate, a light-emitting device, and a lamp which are capable of effectively reducing creeping discharge.

### Solution to Problem

In order to solve the above problems, a mounting substrate according to an aspect of the present invention is a mounting substrate (i) having a mounting surface on which a semiconductor light-emitting element is mounted and (ii) to which a metal body is fitted, the mounting substrate comprising: a conductive member provided on the mounting surface and electrically connected to the semiconductor light-emitting element; a fitting portion to which the metal body is fitted; and a discharge-reducing portion provided between the conductive member and the fitting portion and having a face tilted with respect to a surface of the mounting substrate, thereby increasing a creeping distance between the conductive member and the fitting portion compared to the case where the discharge-reducing portion is not provided.

With this structure, the discharge-reducing portion having a face tilted with respect to a surface of the mounting substrate is provided between the conductive member and the fitting portion. As a result, the creeping distance between the conductive member and the fitting portion is longer than that in the case where there is no discharge-reducing portion.

With this, the occurrence of creeping discharge between the conductive member and the metal body is reduced. Furthermore, since the heat radiation properties are maintained by the metal body, the material of the substrate may be an insulating material such as ceramics. There is therefore no need to form an insulating film unlike in the case of the substrate which uses a metal as its base material. In other words, the mounting substrate according to this aspect is capable of achieving both the reduced occurrence of creeping discharge and the reduced deterioration of heat radiation properties at the same time.

Thus, the mounting substrate according to this aspect makes it possible to effectively reduce the occurrence of creeping discharge.

Furthermore, it may be in the mounting substrate according to an aspect of the present invention.

Specifically, the discharge-reducing portion can be a wall portion having a shape protruding from the surface of the mounting substrate.

Furthermore, in the mounting substrate according to an aspect of the present invention, it may be that the wall portion has a light-transmitting property which allows transmission of light emitted from the semiconductor light-emitting element.

With this structure, light proceeding from the semiconductor light-emitting element in the direction to the wall portion passes through the wall portion and is released outward. The use of this mounting substrate in a light-emitting device can therefore result in the light-emitting device with high light-extraction efficiency.

Furthermore, in the mounting substrate according to an aspect of the present invention, it may be that the wall portion is provided between the conductive member and an edge of the mounting surface, and a height of the wall portion measured from the mounting surface is lower than a height of the semiconductor light-emitting element measured from the mounting surface.

With this structure, the amount of light is reduced by the light shielded by the wall portion among the light emitted from the semiconductor light-emitting element. The use of this mounting substrate in a light-emitting device can therefore result in the light-emitting device with high light-extraction efficiency.

Furthermore, in the mounting substrate according to an aspect of the present invention, it may be that the wall portion includes the insulating material added to the surface of the mounting surface.

With this structure, the wall portion is provided afterward on a substrate main body that is the mounting substrate with no wall portion. In this case, it is possible to efficiently produce mounting substrates of types which are different from each other in withstand voltage performance, using substrate main bodies having the same size and shape, for example.

Furthermore, in the mounting substrate according to an aspect of the present invention, it may be that the discharge-reducing portion is a groove portion recessed into the surface of the mounting substrate.

Specifically, the discharge-reducing portion can be a groove portion having a shape recessed into the surface of the mounting substrate.

Furthermore, in the mounting substrate according to an aspect of the present invention, it may be that the mounting surface has: a first region including (i) a region in which the semiconductor light-emitting element is mounted and (ii) a region in which the conductive member is provided; and a second region outside the first region, and the discharge-reducing portion is provided in the second region.

With this structure, when the semiconductor light-emitting element is mounted on this mounting substrate and the metal body is fitted to the mounting substrate, there is an increase in the creeping distance, for example, between the metal body and the first region that is a region in which the structural elements such as the conductive member and the semiconductor light-emitting element are arranged. This reduces the occurrence of creeping discharge between the metal body and the structural elements arranged in the first region, for example.

Furthermore, in the mounting substrate according to an aspect of the present invention, it may be that the discharge-reducing portion surrounds the first region.

With this structure, the discharge-reducing portion is provided in various directions viewed from the structural elements such as the conductive member and the semiconductor light-emitting element arranged in the first region. This further improves the inhibitory effect on the creeping discharge between these structural elements and the metal body.

Furthermore, in the mounting substrate according to an aspect of the present invention, it may be that the discharge-reducing portion includes: a first discharge-reducing portion which surrounds the conductive member; and a second discharge-reducing portion which surrounds the semiconductor light-emitting element.

With this structure, the conductive member and the semiconductor light-emitting element are surrounded by the respective discharge-reducing portions. This further improves the inhibitory effect on the creeping discharge between the conductive member and the metal body. In addition, when a plurality of semiconductor light-emitting elements is mounted, for example, the occurrence of the creeping discharge between these semiconductor light-emitting elements is also reduced.

Furthermore, in the mounting substrate according to an aspect of the present invention, it may be that the mounting surface is capable of accommodating two or more of the semiconductor light-emitting elements, and the discharge-reducing portion includes a crossing portion which extends crosswise between the two semiconductor light-emitting elements.

With this structure, the crossing portion is provided at a position between two semiconductor light-emitting elements. This reduces the occurrence of creeping discharge between the conductive member and the metal body and also reduces the occurrence of creeping discharge between these two semiconductor light-emitting elements.

Furthermore, a light-emitting device according to an aspect of the present invention comprises: the mounting substrate according to any one of the above aspects; and the semiconductor light-emitting element mounted on the mounting substrate.

With this structure, the light-emitting device capable of effectively reducing the occurrence of creeping discharge is provided.

Furthermore, a lamp according to an aspect of the present invention comprises: the above light-emitting device; and the metal body fitted with the light-emitting device.

With this structure, the lamp capable of effectively reducing the occurrence of creeping discharge is provided.

Furthermore, the lamp according to an aspect of the present invention may comprise an outer shell member having a light-transmitting property and including a helium-containing gas, for covering the light-emitting device.

With this structure, it is possible to improve the properties of radiation, to outside of the lamp, of the heat generated in the light-emitting device.

### BRIEF DESCRIPTION OF DRAWINGS

FIG. 1 is an appearance perspective view of a light-emitting device in Embodiment 1 of the present invention.

FIG. 2 is a top plan of the light-emitting device in Embodiment 1.

FIG. 3 is a cross-sectional view showing an outline of an A-A section in FIG. 2.

FIG. 4 is a conceptual diagram showing a relationship between a wall portion and an increase in creeping distance in the light-emitting device in Embodiment 1.

FIG. 5A shows an outline of a withstand voltage test for checking an inhibitory effect of the wall portion on creeping discharge in Embodiment 1.

FIG. 5B shows a result example of the withstand voltage test shown in FIG. 5A.

FIG. 6 is a conceptual diagram showing a relationship between a groove portion and an increase in creeping distance in the light-emitting device in Embodiment 1.

FIG. 7 shows the first example of another layout pattern of the wall portion in Embodiment 1.

FIG. 8 shows the second example of another layout pattern of the wall portion in Embodiment 1.

FIG. 9 shows the third example of another layout pattern of the wall portion in Embodiment 1.

FIG. 10 shows the fourth example of another layout pattern of the wall portion in Embodiment 1.

FIG. 11A shows the fifth example of another layout pattern of a discharge-reducing portion in Embodiment 1.

FIG. 11B shows the sixth example of another layout pattern of the discharge-reducing portion in Embodiment 1.

FIG. 12A shows an example of a cross-section of a substrate on which a wall portion and a groove portion are arranged.

FIG. 12B shows various examples of a cross-sectional shape of each of the wall portion and the groove portion.

FIG. 13A is a top plan of a light-emitting device in Variation of Embodiment 1.

FIG. 13B is a cross-sectional view showing an outline of a B-B section in FIG. 13A.

FIG. 14 shows the appearance of a lamp in Embodiment 2 of the present invention.

FIG. 15 is a cross-sectional view showing a C-C section in FIG. 14.

FIG. 16 is an exploded perspective view of the lamp in Embodiment 2.

### DESCRIPTION OF EMBODIMENTS

A mounting substrate, a light-emitting device, and a lamp according to embodiments of the present invention shall be described below with reference to the drawings. It is to be noted that each figure is schematic and not necessarily completely accurate illustration.

In each of Embodiments 1 and 2 described hereinbelow, a specific preferred example of the present invention is described. The numerical values, shapes, structural elements, the arrangement and connection of the structural elements, etc. shown in each embodiment are an example and do not limit the present invention. The present invention is limited by the scope of the Claims. Therefore, among the structural elements in each of the following embodiments, structural elements not recited in the independent claims are described as elements which are not always needed to achieve the goal of the present invention, but are included in a more preferred mode.

### Embodiment 1

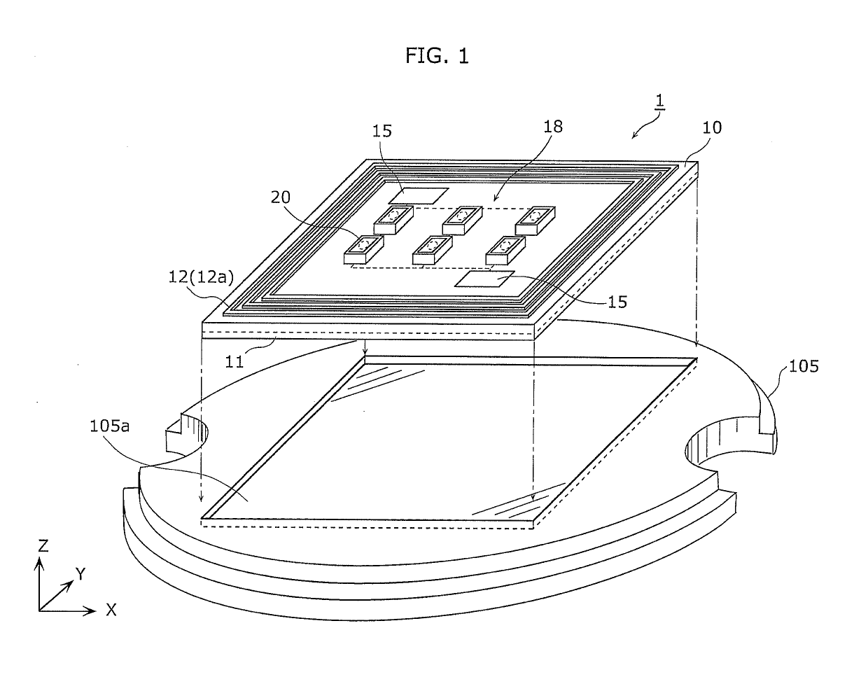

Firstly, the schematic structure of a light-emitting device in Embodiment 1 of the present invention is described with reference to FIGS. 1 to 4.

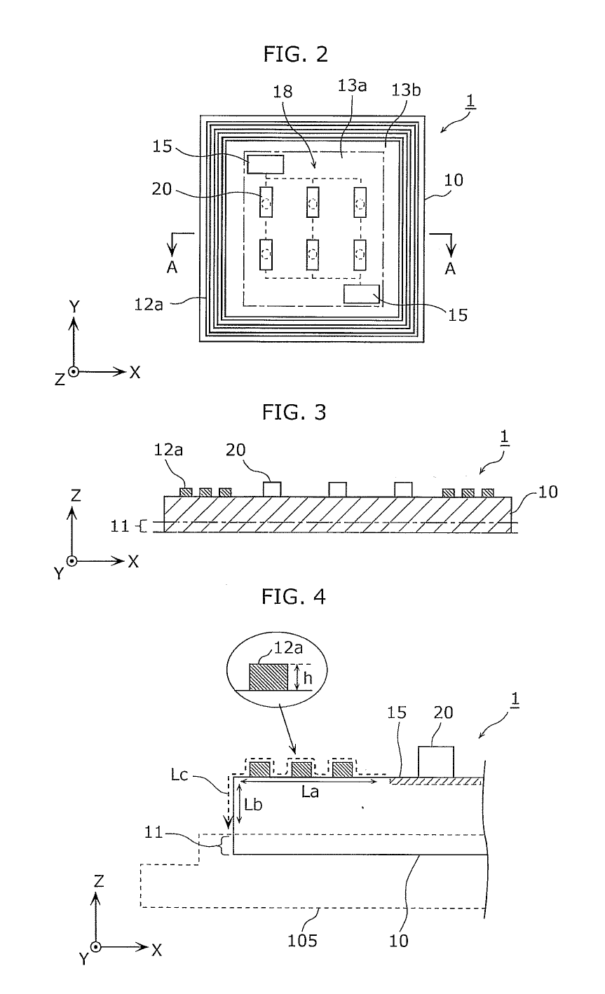

FIG. 1 is an appearance perspective view of a light-emitting device 1 in Embodiment 1 of the present invention, FIG. 2 is a top plan view of the light-emitting device 1 in Embodiment 1, and FIG. 3 is a cross-sectional view showing an outline of an A-A section in FIG. 2.

As shown in FIGS. 1 and 2, the light-emitting device 1 in Embodiment 1 of the present invention is an LED module which emits predetermined illuminating light and includes a substrate 10 and an LED 20 mounted on the substrate 10.

The substrate 10 is an example of the mounting substrate (i) having a mounting surface on which a semiconductor light-emitting element is mounted and (ii) to which a metal body is fitted. The substrate 10 is a ceramic substrate made of alumina in this embodiment. The substrate 10 includes an electrode 15, a fitting portion 11, and a discharge-reducing portion 12. FIGS. 1 to 4 show the substrate 10 which includes a wall portion 12a that is an implementation of the discharge-reducing portion 12.

The LED 20 is an example of the semiconductor light-emitting element and is a surface mount device (SMD)-type LED in this embodiment.

The SMD-type LED 20 includes a resin-made package having a cavity (a concave portion), an LED chip mounted in the cavity, and phosphor-containing resin included in the cavity so as to seal the LED chip.

For this LED chip, a blue luminescence LED chip which emits blue light (hereinafter referred to as “a blue LED chip”) is used, for example. For example, a gallium nitride-based semiconductor light-emitting element which is made of an InGaN-based material and whose center wavelength is 440 nm to 470 nm is used.

For the phosphor-containing resin which seals the LED chip, phosphor-containing resin obtained by dispersing yttrium aluminum garnet (YAG)-based yellow phosphor particles in silicone resin is used so that the LED 20 emits white light.

Specifically, since the yellow phosphor particles are excited by the blue light from the blue LED chip and thereby emit yellow light, the LED 20 emits white light with the yellow light resulting from the excitation and the blue light from the blue LED chip.

It is to be noted that the LEDs 20 are electrically connected to two electrodes 15 through wiring 18 formed by patterning on the mounting surface of the substrate 10 so that each of the LEDs 20 is supplied with electricity through the electrodes 15.

In FIGS. 1 and 2, the pattern of the wiring 18 is shown in dotted lines. The pattern of the wiring 18 shown in FIGS. 1 and 2 is an example, and as long as each of the LEDs 20 can be supplied with necessary electricity, any pattern may be adopted for the wiring 18.

On the fitting portion 11, a metal body 105 is fitted as shown in FIG. 1. In this embodiment, the light-emitting device 1 is fitted to the metal body 105 in a manner that a lower part of the substrate 10 is embedded in a concave portion 105a of the metal body 105. Accordingly, a portion of the lower part of the substrate 10 which is embedded in the concave portion 105a is handled as the fitting portion 11.

The position and shape of the fitting portion 11 is not limited to particular position and shape. For example, in the case where a top flat surface of the metal body 105 is jointed to the underside surface of the substrate 10 (that is a surface opposite to the mounting surface), the underside surface of the substrate 10 is handled as the fitting portion 11.

The metal body 105 not only functions as a member for fitting the light-emitting device 1 on a lamp, but also functions as a heart radiator which efficiently radiates heat of the light-emitting device 1. The lamp including the light-emitting device 1 will be described in Embodiment 2.

The wall portion 12a is located between the fitting portion 11 and the conductive members (such as the electrode 15, the wiring 18, and terminals (not shown) for connecting the wiring 18 and the LED 20) electrically connected to the LED 20, and protrudes from a surface of the substrate 10.

The wall portion 12a in this embodiment has a wall surface which extends vertically (including substantially vertically; the same will apply hereinafter) from a surface of the substrate 10 as shown in FIG. 3. In other words, the wall portion 12a has a face tilted at 90 degrees (including approximate 90 degrees; the same will apply hereinafter) with respect to the surface of the substrate 10.

It is to be noted that “a surface of the substrate 10” includes not only the mounting surface of the substrate 10 and the underside surface thereof, but also four side surfaces present between the mounting surface and the underside surface.

In this embodiment, on the mounting surface, the wall portion 12a is provided in a second region 13b outside a first region 13a in which the conductive members, such as the electrode 15, and the LEDs 20 are included. More specifically, the wall portion 12a surrounds the first region 13a in triple layers. In FIG. 2, the boundary between the first region 13a and the second region 13b is shown in a dashed line.

The wall portion 12 is made of an insulating material. In this embodiment, the wall portion 12a is made of glass containing ceramics and has light-transmitting properties which allow transmission of light emitted from the LED 20.

As shown in FIG. 3, the height of the wall portion 12a measured from the mounting surface is smaller than the height of the LED 20 measured from the mounting surface. Specifically, the height of the wall portion 12a is approximately 30 μm to 50 μm, for example, and the height of the LED 20 measured from the mounting surface is approximately 520 μm, for example.

The wall portion 12a having such features is formed by patterning through screen printing of an inorganic material containing glass or the like onto the mounting surface, for example.

This means that, in this embodiment, the wall portion 12a is a member different from the main body of the substrate 10 and is formed on the main body of the substrate 10 after the main body of the substrate 10 is formed.

Thus, the substrate 10 included in the light-emitting device 1 according to this embodiment includes, in addition to elements which serve a light-emitting function, such as the LED 20 and the electrode 15, the wall portion 12a which protrudes from a surface of the substrate 10. With this, the occurrence of creeping discharge between the conductive member, such as the electrode 15, and the metal body 105 can be reduced.

FIG. 4 is a conceptual diagram showing a relationship between the wall portion 12a and an increase in creeping distance in the light-emitting device 1 in Embodiment 1.

As shown in FIG. 4, assume, for example, that, in FIG. 4, the distance from the electrode 15 to the left-side edge of the substrate 10 is La, and the distance from the left-side edge to the fitting portion 11 is Lb.

In this case, the creeping distance from the electrode 15 to the fitting portion 11 is La+Lb when there is no wall portion 12a. In other words, the creeping distance from the electrode 15 to the metal body 105 in the case were the metal body 105 is fitted to the light-emitting device 1 is La+Lb.

On the other hand, when the wall portion 12a of height h is provided in n layers (n is an integer of 1 or more), the creeping distance Lc from the electrode 15 to the fitting portion 11 is represented by (Expression 1) below.

Lc=La+Lb+2nh (Expression 1)

This means that providing the wall portion 12a on the substrate 10 can increase, by 2nh, the creeping distance between the metal body 105 fitted to the light-emitting device 1 and the conductive member such as the electrode 15, as compared to the case where there is no wall portion 12a.

Specifically, the creeping distance increases by 6h when n is equal to 3 as in this embodiment. For example, assume the case where La+Lb is 2 mm and h is equal to 30 μm in FIG. 3. In this case, the increase in creeping distance due to the wall portion 12a in three layers is 180 μm (=0.18 mm), which means that the creeping distance can increase by a distance equivalent to 9 percent of La+Lb. Thus, increasing the creeping distance by providing the wall portion 12a allows for a reduction in the occurrence of the creeping discharge.

An inhibitory effect of the wall portion 12a on creeping discharge is explained with a result example of a withstand voltage test.

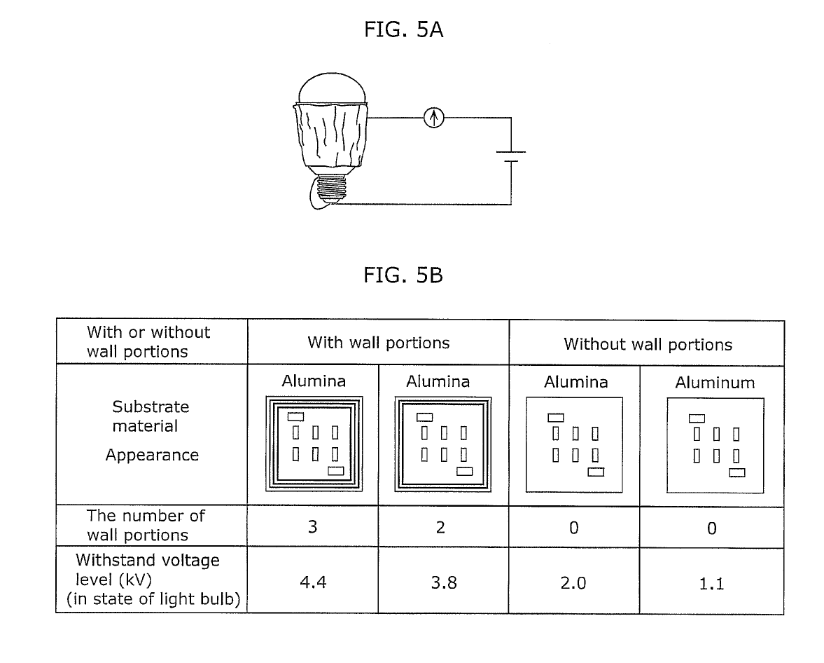

FIG. 5A shows an outline of the withstand voltage test for checking the inhibitory effect of the wall portion 12a on creeping discharge in Embodiment 1.

As shown in FIG. 5A, a bulb-shaped lamp which has the light-emitting device 1 and the metal body 105 inside is prepared, and an outer case of the lamp is covered with aluminum foil. Here, the outer case has conducting properties and is in contact with the metal body 105.

Furthermore, a center electrode and a surrounding electrode are short-circuited in a base portion by an electric wire, and a predetermined voltage is applied between the electric wire and the aluminum foil. By doing so, the predetermined voltage is applied between the metal body 105 and the conductive member such as the electrode 15.

The withstand voltage test as above continues to run for one minute, and when a leakage current of 0.5 mA or more is not found during the test, then the test is passed.

The same or like test was conducted under different conditions in terms of the number of wall portions 12a, the material of the substrate 10, and the like, as a result of which the values shown in FIG. 5B were obtained.

FIG. 5B shows a result example of the withstand voltage test shown in FIG. 5A.

As shown in FIG. 5B, when the wall portion 12a was provided in three layers and the substrate 10 was made of alumina as in Embodiment 1, the withstand voltage level was 4.4 kV. This means that a current of 0.5 mA or more was not measured until the potential difference between the conductive member on the substrate 10 and the metal body 105 became 4.4 kV.

When the material of the substrate 10 was alumina likewise and the wall portion 12a was provided in two layers, the withstand voltage level was 3.8 kV.

On the other hand, when the material of the substrate 10 was alumina likewise and the wall portion 12a was not provided, the withstand voltage level was 2.0 kV, and when the material of the substrate 10 was aluminum (with an insulating coating), which is a conductive material, and the wall portion 12a was not provided, the withstand voltage level was 1.1 kV.

This shows that when the substrate 10 is provided with the wall portion 12a, the occurrence of creeping discharge is reduced compared to at least the case where the substrate 10 is provided without the wall portion 12a. In addition, the above shows that at least increasing the number of wall portions 12a improves the inhibitory effect on the creeping discharge.

It is to be noted that in this test, increasing the number of wall portions 12a increases the creeping distance to thereby improve the inhibitory effect on the creeping discharge. However, since the increase in creeping distance due to the wall portions 12a in n layers is 2nh as indicated in the above (Expression 1), it may also be possible to increase the height h of the wall portion 12a without changing the number of wall portions 12a to increase the creeping distance.

Furthermore, the discharge-reducing portion 12 in this embodiment may take a different form from the wall portion 12a when provided in the substrate 10. For example, the substrate 10 may be provided with a groove portion recessed into a surface of the substrate 10 as the discharge-reducing portion 12.

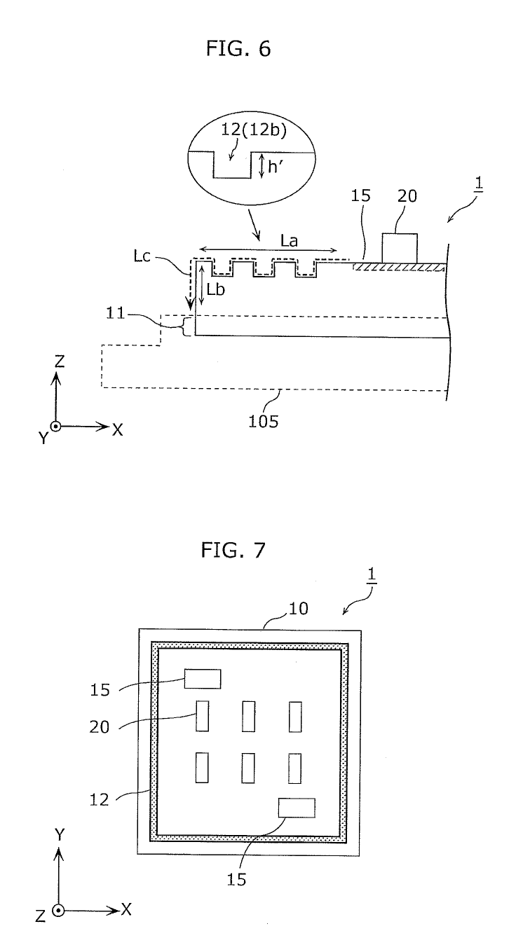

FIG. 6 is a conceptual diagram showing a relationship between the wall portion 12b and an increase in creeping distance in the light-emitting device 1 in Embodiment 1.

In FIG. 6, the creeping distance from the electrode 15 to the fitting portion 11 is La+Lb when there is no wall portion 12a. In other words, the creeping distance from the electrode 15 to the metal body 105 in the case were the metal body 105 is fitted to the light-emitting device 1 is La+Lb.

On the other hand, assume the case where, as shown in FIG. 6, an inner surface defining the groove portion 12b is tilted at 90 degrees with respect to the surface of the substrate 10, the length of the inner surface in the z-axis direction (that is, the depth of the groove portion 12b) is h′, and the groove portion 12b is provided in n layers (n is an integer of 1 or more). In this case, the creeping distance Lc from the electrode 15 to the fitting portion 11 is represented by (Expression 2) below.

Lc=La+Lb+2nh′ (Expression 2)

This means that providing the groove portion 12b on the substrate 10 can increase, by 2nh′, the creeping distance between the metal body 105 fitted to the light-emitting device 1 and the conductive member such as the electrode 15, as compared to the case where there is no groove portion 12b.

For example, assume the case where the groove portion 12b is provided in three layers around the conductive member such as the electrode 15 as in the case of the wall portion 12a shown in FIG. 2.

In this case, when La+Lb is 2 mm and h is equal to 30 μm in FIG. 6, the increase in creeping distance due to the groove portion 12b in three layers is 180 μm (=0.18 mm). In other words, the creeping distance increases by a distance equivalent to 9 percent of La+Lb.

Thus, by providing the substrate 10 with the groove portion 12b, it is possible to obtain the inhibitory effect on the creeping discharge as in the above-described case where the substrate 10 is provided with the wall portion 12a.

It is to be noted that the layout pattern of the discharge-reducing portion 12 (the wall portion 12a and the groove portion 12b in this embodiment) is not limited to a particular pattern.

For example, the wall portion 12a in this embodiment is provided in three layers so as to tightly surround the electrode 15 and the LED 20 as shown in FIG. 2.

However, such a layout pattern of the discharge-reducing portion 12 is an example, and various other layout patterns of the discharge-reducing portion 12 can be adopted on the substrate 10. In any of the cases, the inhibitory effect on the creeping discharge is exerted.

The following describes other examples of the layout pattern of the discharge-reducing portion 12 with reference to FIGS. 7 to 11B. This means that FIGS. 7 to 11B show applicable examples of the layout patterns of the respective wall portion 12a and groove portion 12b.

FIG. 7 shows the first example of another layout pattern of the discharge-reducing portion 12 in Embodiment 1.

In each of FIGS. 7 to 11B, the discharge-reducing portion 12 is shown by a dotted region so that the layout pattern of the discharge-reducing portion 12 is clearly visible.

As shown in FIG. 7, the substrate 10 may be provided with only one discharge-reducing portion 12. Specifically, it is not necessary that a plurality of discharge-reducing portions 12 be present between the conductive member, such as the electrode 15, and the fitting portion 11; it is sufficient that at least one discharge-reducing portion 12 is provided between the conductive member, such as the electrode 15, and the fitting portion 11.

Even in this case, increasing the height of the wall portion 12a or the depth of the groove portion 12b can increase the creeping distance as described above, which makes it possible to fabricate the substrate 10 which satisfies required withstand voltage performance.

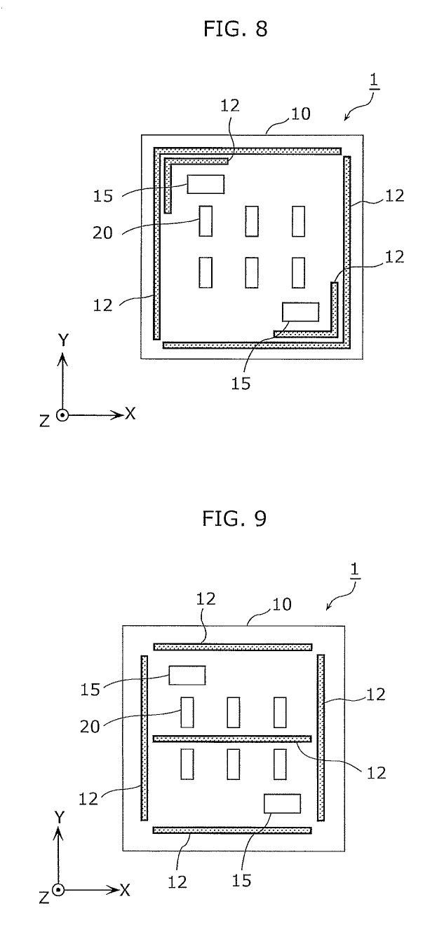

FIG. 8 shows the second example of another layout pattern of the discharge-reducing portion 12 in Embodiment 1.

As shown in FIG. 8, the substrate 10 has a plurality of discharge-reducing portions 12 independent of each other.

For example, in the case where the electrode 15 and the plurality of LEDs 20 are surrounded collectively by the discharge-reducing portions 12, the electrode 15 and the plurality of LEDs 20 may be surrounded by the plurality of independent discharge-reducing portions 12 as shown in FIG. 8. In other words, the electrode 15 and the plurality of LEDs 20 may be surrounded by the discharge-reducing portion 12 which is composed of a plurality of divisions.

Furthermore, as shown in FIG. 8, the number of layers of the discharge-reducing portion 12 may be different depending on locations. For example, in the case where there is no discharge-reducing portion 12, it may be possible that the discharge-reducing portion 12 is provided in two layers only between the fitting portion 11 and the electrode 15 which is the conductive member whose creeping distance to the fitting portion 11 is shortest while one discharge-reducing portion 12 is provided at the remaining position.

Thus, it may be possible that the plurality of discharge-reducing portions 12 is provided at a position where the creeping discharge is likely to occur while a smaller number of discharge-reducing portions 12 are provided at the remaining position. It is to be noted that there is no need to provide the discharge-reducing portion 12 at the position, for example, where the creeping discharge seems unlikely to occur.

By thus determining the layout pattern of the discharge-reducing portion 12 according to whether or not the creeping discharge is likely to occur at the position, the occurrence of creeping discharge is reduced, and the discharge-reducing portion 12 which will ultimately be useless is prevented from being formed.

FIG. 9 shows the third example of another layout pattern of the discharge-reducing portion 12 in Embodiment 1.

As shown in FIG. 9, the substrate 10 may include, in addition to four discharge-reducing portions 12 which surround the first region 13a, the discharge-reducing portion 12 which extends crosswise between at least two of the LEDs 20. The discharge-reducing portion 12 which extends crosswise between the two LEDs 20 is an example of a crossing portion.

With this, the occurrence of creeping discharge between the electrode 15 and the metal body 105 is reduced, and the occurrence of creeping discharge between the two LEDs 20 is also reduced.

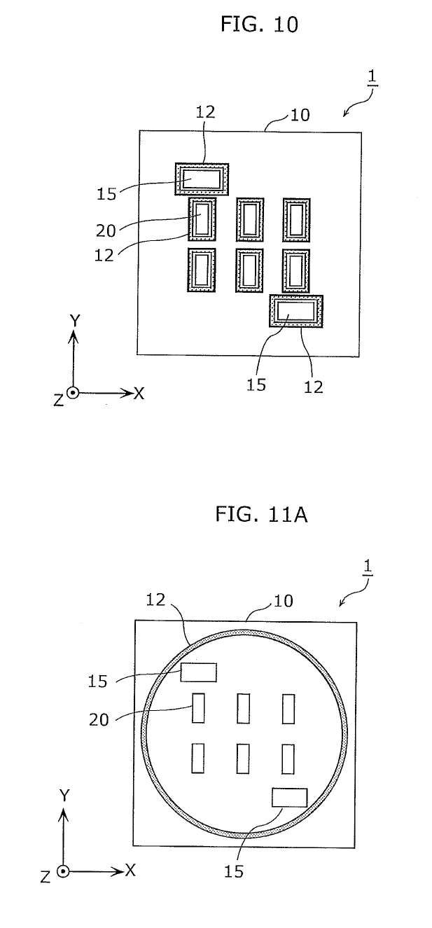

FIG. 10 shows the fourth example of another layout pattern of the discharge-reducing portion 12 in Embodiment 1.

As shown in FIG. 10, the substrate 10 includes the discharge-reducing portion 12 which surrounds each electrode 15, and the discharge-reducing portion 12 which surrounds each LED 20.

The discharge-reducing portion 12 which surrounds each electrode 15 is an example of a first discharge-reducing portion, and the discharge-reducing portion 12 which surrounds each LED 20 is an example of a second discharge-reducing portion.

With each of the electrode 15 and the LED 20 surrounded by the individual discharge-reducing portion 12, the inhibitory effect on the creeping discharge between the electrode 15 and the metal body 105 improves more. In addition, the occurrence of creeping discharge between the LEDs 20 is also reduced.

As above, FIGS. 7 to 10 show various layout patterns of the discharge-reducing portion 12 which are made by straight lines when viewed from above. However, the layout pattern of the discharge-reducing portion 12 may be partially or entirely made by curved lines when viewed from above.

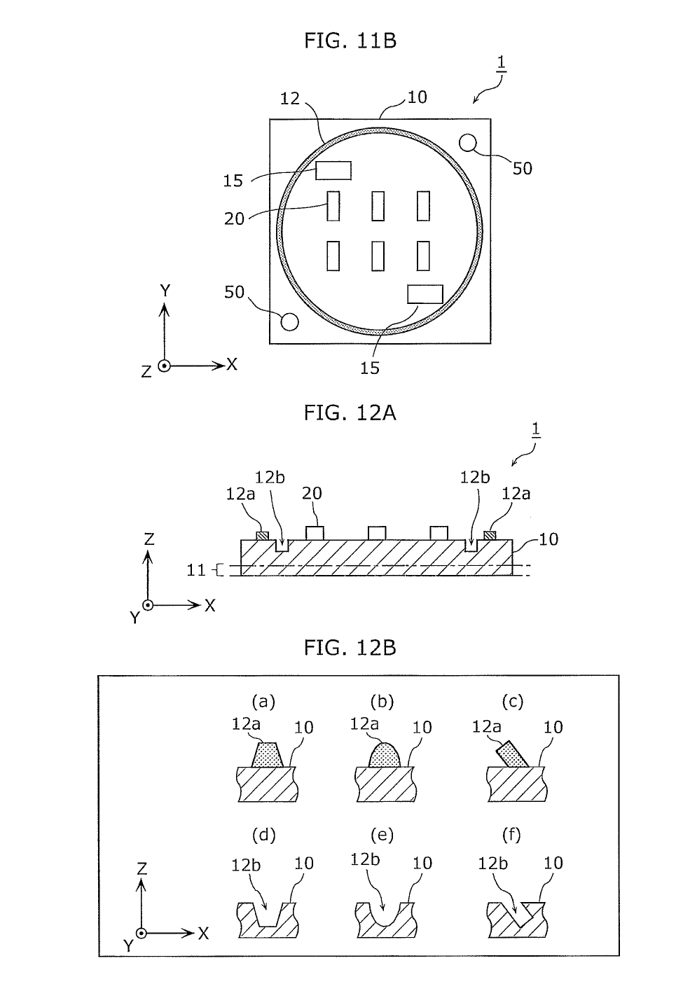

FIG. 11A shows the fifth example of another layout pattern of the discharge-reducing portion 12 in Embodiment 1.

For example, as shown in FIG. 11A, the substrate 10 may be provided with the discharge-reducing portion 12 which has a circular shape when viewed from above. Even in this case, the creeping distance between the conductive member, such as the electrode 15, and the metal body 105 increases, which improves the inhibitory effect on the creeping discharge.

In addition, including curved lines into at least part of the layout pattern of the discharge-reducing portion 12 as above allows, for example, flexible designing of the layout pattern of the discharge-reducing portion 12 according to the positions of elements, such as the electrode 15, provided on the substrate 10.

FIG. 11B shows the sixth example of another layout pattern of the discharge-reducing portion 12 in Embodiment 1.

For example, assume the case where the substrate 10 is provided with a fitting hole 50 for fitting the light-emitting device 1 to another member such as the metal body 105. In this case, for example, the creeping distance between the metal body 105 and the conductive member which is closest to the fitting hole 50 is shorter than that in the case where there is no fitting hole 50.

However, in this case, the discharge-reducing portion 12 is provided between the conductive member and the fitting hole 50 as shown in FIG. 11B, so that the inhibitory effect on the creeping discharge due to the presence of the fitting hole 50 can be prevented from decreasing.

Furthermore, as shown in FIG. 11A, the discharge-reducing portion 12 is provided at a position other than corner parts of the substrate 10, which makes it possible that other elements such as the fitting hole 50 can be provided on the corner parts of the substrate 10 as shown in FIG. 11B.

It is to be noted that the various layout patterns of the discharge-reducing portion 12 shown in FIGS. 7 to 11B are applicable with both the wall portion 12a and the groove portion 12B.

Furthermore, the wall portion 12a and the groove portion 12b may be mixed and arranged on the substrate 10.

FIG. 12A shows an example of a cross-section of the substrate 10 on which the wall portion 12a and the groove portion 12b are arranged.

As shown in FIG. 12A, even in the case where the wall portion 12a and the groove portion 12b are mixed and arranged on the substrate 10, the effect of increased creeping distance because of each of the wall portion 12a and the groove portion 12b is not affected. Specifically, the inhibitory effect on the creeping discharge in the substrate 10 improves by providing the substrate 10 with the wall portion 12a and the groove portion 12b.

Furthermore, for example, by forming a required number of wall portions 12a on each of the substrates 10 having the groove portion 12b, it is possible to efficiently produce substrates 10 of multiple types which are different from each other in withstand voltage performance.

Furthermore, each of the wall portion 12a and the groove portion 12b is formed vertically, as a whole, relative to a surface of the substrate 10 in this embodiment as shown in FIGS. 4 and 6, for example. Specifically, in this embodiment, the discharge-reducing portion 12 has a face tilted at 90 degrees with respect to the surface of the substrate 10.

However, it may be that the discharge-reducing portion 12 does not have the face tilted at 90 degrees with respect to the surface of the substrate 10.

FIG. 12B shows various examples of a cross-sectional shape of each of the wall portion 12a and the groove portion 12b.

More specifically, FIG. 12B shows plural examples of the wall portion 12a and the groove portion 12b which each have a face tilted (at an angle other than 90 degrees) with respect to a surface of the substrate 10 so as to increase the creeping distance.

As shown in (a) and (b) in FIG. 12B, the cross-sectional shape of the wall portion 12a may be a trapezoid and may alternatively be composed of curved lines only. In short, the cross-sectional shape of the wall portion 12a may be a shape other than a rectangle.

Furthermore, as shown in (c) in FIG. 12B, the wall portion 12a may be provided not vertically, but at an angle, as a whole, to a surface of the substrate 10.

Likewise, as shown in (d) and (e) in FIG. 12B, the cross-sectional shape of the groove portion 12b may be a trapezoid and may alternatively be composed of curved lines only. In addition, as shown in (f) in FIG. 12B, the groove portion 12b may be formed by obliquely scraping the substrate 10 from a surface thereof.

It is to be noted that the shape of the cross-section of each of the wall portion 12a and the groove portion 12b, cut vertically to the longitudinal direction (the Y-axis direction in FIG. 12B), is not limited to the various shapes shown in FIG. 12B and may be another shape such as a T-shape.

In other words, it is sufficient that the discharge-reducing portion 12 has a face tilted with respect to the surface of the substrate 10. In this case, regardless of the angle between the face and the surface of the substrate 10, the discharge-reducing portion 12 can increase more the creeping distance between the conductive member and the metal body 105 which are present across the discharge-reducing portion 12, as compared to the case where there is no discharge-reducing portion 12.

Thus, various shapes may be adopted for the cross-sectional shape of the discharge-reducing portion 12 (the wall portion 21a and the groove portion 12b).

Furthermore, it is not necessary that the discharge-reducing portion 12 have an elongated shape when viewed from above. The discharge-reducing portion 12 may be, for example, a semispherical structure protruding from the substrate 10. Alternatively, the discharge-reducing portion 12 may be a hole which does not penetrate the substrate. In any of the cases, the creeping distance via the discharge-reducing portion 12 increases compared to the case where there is no discharge-reducing portion 12.

As described above, the light-emitting device 1 in this embodiment includes the discharge-reducing portion 12 having a face tilted with respect to the surface of the substrate 10, at a position between the conductive member, such as the electrode 15, and the fitting portion 11. With this, the creeping distance between the conductive member and the metal body 105 fitted to the fitting portion 11 can be increased.

As a result, the occurrence of creeping discharge between the conductive member and the metal body 105 is reduced.

Furthermore, even in the case where an insulating material such as ceramics is used as the material of the substrate 10, a decrease in the luminous efficacy of the LED 20 due to a temperature rise can be reduced because the heat radiation properties are maintained by the metal body 105.

Furthermore, in the case where an insulating material such as ceramics is used as the material of the substrate 10, there is no need to form an insulating film unlike in the case of the substrate which uses a metal as its base material. In other words, the substrate 10 is capable of achieving both the reduced occurrence of creeping discharge and the reduced deterioration of heat radiation properties at the same time.

Furthermore, the wall portion 12a can be provided on the main body of the substrate 10 after the main body of the substrate 10 is formed. Thus, it is possible, for example, that main bodies of the substrates 10 having the same size and shape are fabricated first, then the wall portions 12a with different heights and layout patterns are formed on the respective substrates 10.

Likewise, the groove portion 12b can be provided in the main body of the substrate 10 after the main body of the substrate 10 is formed.

This makes it possible to efficiently produce substrates 10 of multiple types which are different from each other in withstand voltage performance.

It is to be noted that, in this embodiment, the LED 20 is an SMD-type LED and includes a package, an LED chip, and phosphor-containing resin which seals the LED chip. However, the LED 20 may be an LED chip per se.

Specifically, the light-emitting device 1 may be a chip-on-board (COB)-type light-emitting module.

This means that the semiconductor light-emitting element which is adopted as a light source in the light-emitting device 1 is not limited to a particular form and may be any semiconductor light-emitting element as long as it can be mounted on the mounting surface of the substrate 10.

For example, it may be that, as the LED 20, a bare chip which emits blue light is die-bonded onto the substrate 10 using a light-transmissive die-attach material (a die-bond material). Furthermore, in this case, as described above, each LED 20 is sealed using phosphor-containing resin obtained by dispersing YAG-based yellow phosphor particles in silicone resin, with the result that each LED 20 can emit white light through the phosphor-containing resin.

Furthermore, in this embodiment, the wall portion 12a is made of glass containing ceramics. However, it is sufficient that the wall portion 12a is made of an insulating material; the wall portion 12a may be made of resin, for example.

Furthermore, although the wall portion 12a has light-transmitting properties, it is not necessary that the wall portion 12a have light-transmitting properties, for example, in the case where the light released laterally from the light-emitting device 1 is not given much importance.

Furthermore, it may be that the wall portion 12a is not provided on the main body of the substrate 10 after the main body of the substrate 10 is formed, and the wall portion 12a and the main body of the substrate 10 may be integrally formed through resin injection molding, for example.

Furthermore, the substrate 10 may be a substrate of a type other than the ceramic substrate made of alumina. For example, the substrate 10 may be a substrate made of an insulating material, such as glass or resin, other than ceramics.

Furthermore, the number and positions of LEDs 20 included in the light-emitting device 1 are not limited to particular number and positions. In addition, the shape and size of the substrate 10 are not limited to particular shape and size, either. This means that the discharge-reducing portion 12 in the substrate 10 exerts the inhibitory effect on the creeping discharge independently of the number and positions of LEDs 20 and the shape and size of the substrate 10.

For example, the discharge-reducing portion 12 may be provided on a side surface of the substrate 10 which is a part of the surface thereof. For example, in FIG. 3, the wall portion 12a may be provided at a position on the left-side surface of the substrate 10, which is a position other than the fitting portion 11, so as to protrude from the left-side surface. At the same position, the grove portion 12b may be provided so as to be recessed into the left-side surface.

Even in the case where the discharge-reducing portion 12 is present on the above position, the creeping distance between the conductive member on the mounting surface and the metal body 105 can be increased, with the result that the occurrence of creeping discharge between the conductive member and the metal body 105 is reduced.

Furthermore, it may be that the metal body 105 fitted to the substrate 10 does not function as a heat radiator. For example, in the case where a temperature rise in the light-emitting device 1 does not affect the luminous efficacy of the LED 20, it is sufficient, for example, that the metal body 105 only functions as a member for holding the light-emitting device 1 and does not function as a heat radiator.

### Variation of Embodiment 1

As Variation of Embodiment 1, a light-emitting device having an elongated shape is described.

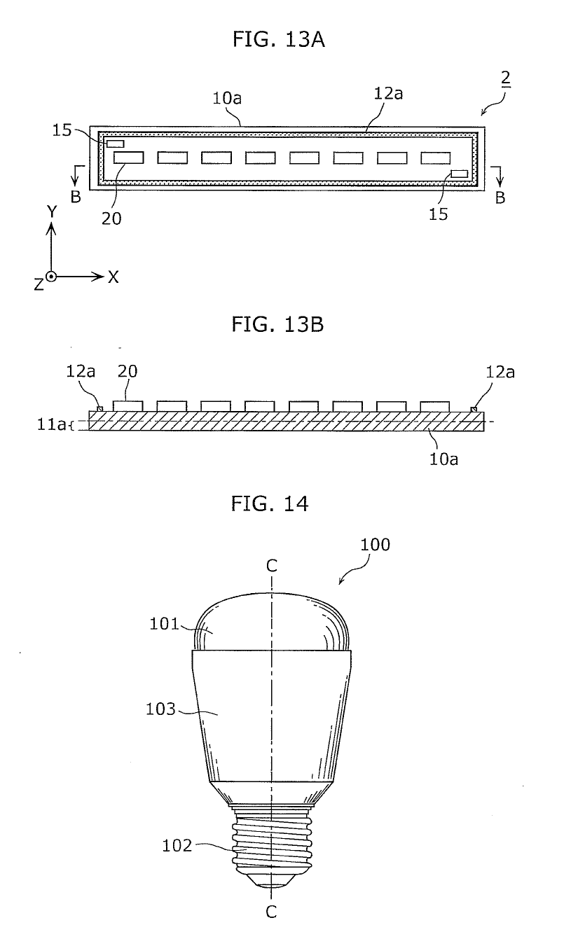

FIG. 13A is a top plan of a light-emitting device 2 in Variation of Embodiment 1, and FIG. 13B is a cross-sectional view showing a B-B section in FIG. 13A.

The light-emitting device 2 shown in FIGS. 13A and 13B is an example of the light-emitting module which is incorporated as a light source into an LED tube lamp, for example.

The light-emitting device 2 includes a substrate 10a having an elongated shape, and a plurality of LEDs 20 arranged in a line. At both ends of the substrate 10a, respective electrodes 15 are provided, and the LEDs 20 are electrically connected to both the electrodes 15 through wiring (not shown).

The substrate 10a is another example of the mounting substrate and is, for example, a ceramic substrate made of alumina. Furthermore, the substrate 10a includes a fitting portion 11a to which a metal body is fitted, as in the case of the substrate 10 in Embodiment 1.

The substrate 10a further includes a wall portion 12a. The wall portion 12a is located between a conductive member, such as the electrode 15, and the fitting portion 11a, and protrudes from a surface of the substrate 10a.

Specifically, on the substrate 10a, the wall portion 12a is provided on the mounting surface and surrounds the LEDs 20 and the conductive member such as the electrode 15.

Even with the elongated substrate 10a as above, providing the wall portion 12a between the conductive member, such as the electrode 15, and the fitting portion 11a allows for an increase in the creeping distance between the conductive member and the metal body fitted to the fitting portion 11a. As a result, the occurrence of creeping discharge between the conductive member and the metal body can be reduced.

Also in the case where the substrate 10a is provided with the groove portion 12b which replaces or is added to the wall portion 12a, the creeping discharge in the substrate 10a is reduced.

In addition, the layout pattern of the substrate 10a with the wall portion 12a and the groove portion 12b is not limited to the pattern shown in FIG. 13A, which means that various layout patterns are available. For example, one of the layout patterns shown in FIGS. 2 and 7 to 11B may be adopted.

### Embodiment 2

Hereinbelow, an example of application of the light-emitting device 1 in Embodiment 1 to a lamp is explained based on Embodiment 2.

Specifically, an example where the light-emitting device 1 in Embodiment 1 is applied to a bulb-shaped lamp is explained with reference to FIGS. 14 to 16.

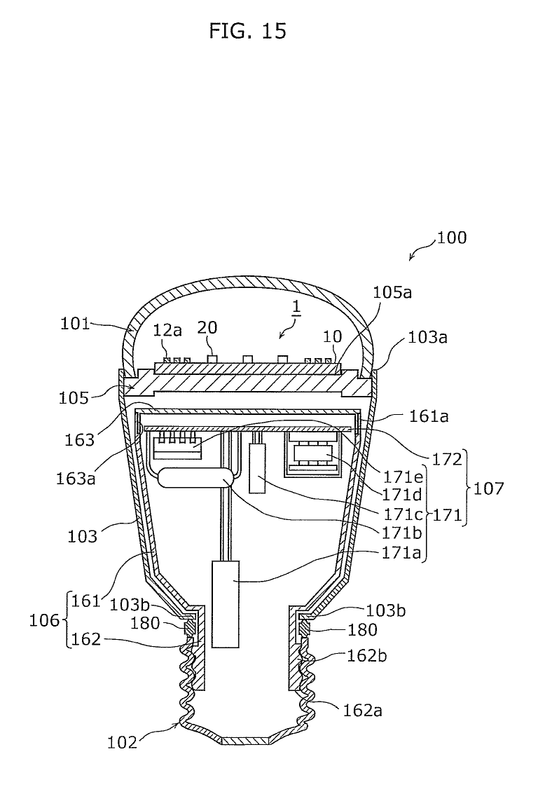

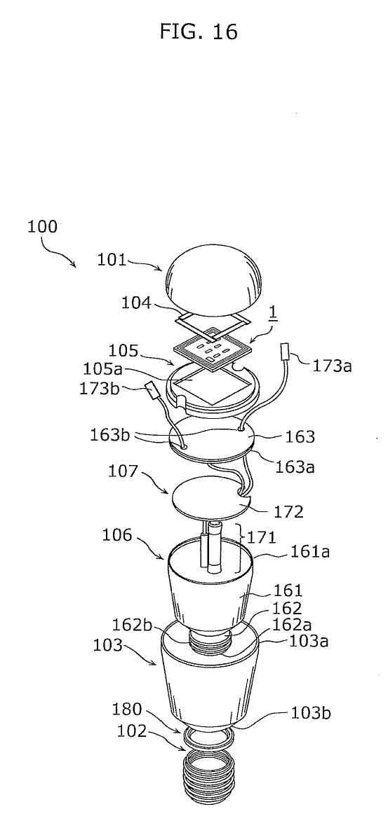

FIG. 14 shows the appearance of a lamp 100 in Embodiment 2 of the present invention, FIG. 15 is a cross-sectional view showing a C-C section in FIG. 14, and FIG. 16 is an exploded perspective view of the lamp 100 in Embodiment 2.

This lamp 100 is a bulb-shaped LED lamp and has a lamp cover including a base 102, a globe 101, and an outer case 103 located between the globe 101 and the base 102.

The globe 101 is an example of an outer shell member and is a spherical light-transmissive cover for radiating light from the light-emitting device 1 to outside of the lamp. The light-emitting device 1 is covered with this globe 101. Furthermore, a treatment for light diffusion such as a frosted glass treatment has been applied to the globe 101 in order to diffuse light released from the light-emitting device 1.

This globe 101 has a shape such that it becomes smaller towards the opening thereof, and the opening end of globe 105 is provided in contact with the top surface of the metal body 105. The metal body 105 functions, in the lamp 100, not only as a member for fitting the light-emitting device 1 which is a light source, but also as a member which promotes heat radiation of the light-emitting device 1.

The globe 101 is bonded to the outer case 103 by heat-resistant silicone adhesive.

It is to be noted that the shape of the globe 101 is not limited to the spherical shape and may be semispherical, spheroidal, or oblate spheroidal. In addition, the material of the globe 101 is a glass material in this embodiment, but the material of the globe 101 is not limited to the glass material, and it may be possible that the globe 101 is formed of synthetic resin or the like material.

The base 102 is a power receiving unit for receiving alternating-current power through two contacts. The power received by the base 102 is input to a power input unit of a circuit board 172 through a lead line (not shown). The base 102 is a metallic tube having a bottom on which a center electrode surrounded by an insulating material is provided. In this embodiment, the base 102 is of an E-type.

The outer case 103 is a tube which houses an inner case 106, and is thermally bonded to the light-emitting device 1 via the metal body 105. This outer case 103 is a metallic heat-radiating case which is tubular in structure with two openings in the vertical direction, and includes a first opening end 103a which defines a globe 101-side opening and a second opening end 103b which defines a base 102-side opening.

In this embodiment, the outer case 103 is made of an aluminum alloy material. Furthermore, the outer case 103 has a surface treated with alumite, which improves thermal emittance.

The second opening end 103b of the outer case 103 is in contact with an insulating ring 180.

The light-emitting device 1 is a light-emitting module which includes the substrate 10, the plurality of LEDs 20, and the wall portion 12a, as described in Embodiment 1.

Each of the LEDs 20 is an SMD-type LED, for example, which emits white light because of a blue LED chip and phosphor-containing resin containing yellow phosphor particles.

The light-emitting device 1 is provided with two connectors 173a and 173b which are connected to a lead line extending from a power output unit formed on the circuit board 172. Through these two connectors 173a and 173b, direct-current power is supplied to the light-emitting device 1 to thereby cause the LED 20 to emit light.

The metal body 105 is a holder (a module plate) composed of a metal substrate for placing the light-emitting device 1 and is formed through aluminum die casting into a disc shape, for example. This metal body 105 functions as a heat radiator which transfers heat generated by the light-emitting device 1 to the outer case 103.

The metal body 105 is mounted on the first opening end 103a of the outer case 103 and thereby is thermally connected to the light source of the light-emitting device 1 and the outer case 103, and a side portion of the metal body 105 is in contact with an upper inner surface of the outer case 103.

In other words, the metal body 105 is embedded in the outer case 103 on the first opening end 103a side. In the metal body 105, the concave portion 105a for placing the light-emitting device 1 is formed. In this embodiment, the concave portion 105a is formed into a rectangular shape the same as the shape of the substrate 10 of the light-emitting device 1.

The light-emitting device 1 placed in the concaved portion 105a is held between a metal clamp 104 and the concaved portion 105a. It is to be noted that the outer case 103 and the metal body 105 provided with the light source may be a single member.

The inner case 106 is a resin-made tube which houses a lighting circuit 107 having a circuit element group 171, and includes: a first case part 161 which is a cylinder having an inverse cone and trapezoid shape substantially the same as the shape of the outer case 103; and a second case part 162 which is a cylinder having a shape substantially the same as the shape of the base 102.

This inner case 106 not only functions as an electrically insulating case which prevents the circuit element group 171 from contacting the metallic outer case 103, but also functions as a heat transfer medium which transfers heat generated by the circuit element group 171 to the base 102 and thereby radiates the heat.

In the inner case 106, the first case part 161 and the second case part 162 are integrally formed through injection molding.

As the material of the inner case 106, polybutylene terephthalate (PBT) is used which contains 15% to 40% alumina having a grain size of 1 μm to 10 μm and whose thermal conductivity is 1.5 (W/m·K), for example.

The first case part 161 of the inner case 106 has a first opening 161a which opens toward the light-emitting device 1 (in the direction opposite to the second case part 162).

The second case part 162 of the inner case 106 has a second opening 162a which opens toward the base 102 (in the direction opposite to the first case part 161). The second case part 162 has a structure such that an outer periphery thereof is in contact with an inner periphery of the base 102.

In this embodiment, a threaded portion 162b to be threaded into the base 102 is formed on the outer periphery of the second case part 162, and through the threaded portion 162b, the second case part 162 is in contact with the base 102. With this, the heat generated by the circuit element group 171 is transferred from the inner case 106 to the base 102 and thereby is radiated outward.

The first opening 161a of the first case part 161 on the metal body 105 side is fitted with a resin cap 163. On the metal body 105 side, the inner case 106 is sealed with the resin cap 163.

The resin cap 163 has a substantially disc shape, and on an outer periphery end thereof on the inner surface side, a ring-shaped protrusion 163a which protrudes in the thickness direction of the inner case 106 is formed. On an inner periphery of the protrusion 163a, a plurality of locking claws (not shown) for locking the circuit substrate 172 is formed.

The protrusion 163a is designed such that it can be embedded into an end of the first opening 161a of the first case part 161 of the inner case 106. This resin cap 163 can be formed using a material the same as the material of the inner case 106. Furthermore, in the resin cap 163, a through hole 163b is formed through which the lead line for supplying the light-emitting device 1 with electricity runs.

The lighting circuit 107 includes: the circuit element group 171 included in a circuit (a power supply circuit) for causing the LED 20 of the light-emitting device 1 to emit light; and the circuit board 172 on which each circuit element in the circuit element group 171 is mounted.

The circuit element group 171 includes a plurality of circuit elements for generating, using the electricity received by the base 102, electricity for causing the light source (the light-emitting device 1) to emit light. The circuit element group 171 exchanges the alternating-current power received by the base 102 with direct-current power and supplies the direct-current power to the LED 20 of the light-emitting device 1 via the connectors 173a and 173b.

This circuit element group 171 includes: a first capacitor element 171a which is an electrolytic capacitor (a vertical capacitor); a second capacitor element 171b which is a ceramic capacitor (a horizontal capacitor); a resistor element 171c; a voltage converter element 171d composed of a coil; and a semiconductor element 171e which is an integrated circuit of intelligent power device (IPD).

The circuit board 172 is a disc-shaped printed board and has one surface with the circuit element group 171 mounted thereon. This circuit board 172 is held on the resin cap 163 by the locking claws of the resin cap 163 as described above.

The insulating ring 180 is a ring-shaped structure held between the opening end of the base 102 and the second opening end 103b of the outer case 103 and is made of resin which electrically insulates the base 102 and the outer case 103.

In the lamp 100 in this embodiment structured as above, the heat generated by the light-emitting device 1 is released to outside via the metal body 105 and the outer case 103.

With this, a decrease in the luminous efficacy of the LED 20 due to a temperature rise is reduced. Furthermore, as described in Embodiment 1, the substrate 10 of the light-emitting device 1 is provided with the wall portion 12a, which reduces the occurrence of creeping discharge between the metal body 105 and the conductive member, such as the electrode 15, on the mounting surface of the substrate 10.

It is to be noted that the lamp 100 in Embodiment 2 is an example of the bulb-shaped lamp which includes the light-emitting device 1 in Embodiment 1, and may have a structure other than the structure shown in FIGS. 14 to 16.

Furthermore, as described in Variation of Embodiment 1, the LED tube lamp may include the light-emitting device 2 having an elongated shape, for example.

Furthermore, for example, by forming the light-emitting device 2 such that the shape of the whole light-emitting device 2 is defined by curved lines along with the ring shape of a ring-shaped lamp, it is possible to provide the light-emitting device 2 in the ring-shaped lamp without difficulty.

Furthermore, the height and layout pattern of the wall portion 12a in the light-emitting device 1 or 2 which is adopted as a light source in a lamp is not limited to particular height and layout pattern. For example, appropriate height and layout pattern of the wall portion 12a may be determined according to the withstand voltage performance required for the lamp.

Furthermore, as the discharge-reducing portion 12 with which the light-emitting device 1 or 2 adopted as a light source in a lamp is provided, the groove portion 12b may replace or is added to the wall portion 12a.

Thus, the light-emitting devices 1 and 2 are not limited to lamps of particular types and can be used as light sources in lamps of various types.

In the lamp in which the light-emitting device 1 or 2 is adopted as a light source, helium may be included, for example, in the globe or the outer shell member which is tubular glass or the like.

Here, since helium has a relatively high thermal conductivity compared to other gas, the heat generated by the light-emitting device 1 or 2 (the LED 20) is efficiently transmitted and radiated into the helium-containing gas within the outer shell member. Since the thermal conductivity of the outer shell member formed of glass, for example, is higher than the thermal conductivity of helium, the heat generated by the light-emitting device 1 or 2 (the LED 20) is efficiently transmitted through the helium-containing gas to the outer shell member which is in contact with the gas. As a result, the heat generated by the light-emitting device 1 or 2 (the LED 20) is released to outside of the lamp through the outer shell member.

Here, since the mean free path of helium is greater than the mean free path of air, helium mixed as an atmosphere gas of the light-emitting device 1 or 2 will decrease the insulation-related withstand voltage level in the lamp including the light-emitting device 1 or 2, as compared to the case where the atmosphere gas is the air only.

Specifically, the lamp including the light-emitting device 1 or 2 satisfies (Expression 3) below where V represents the insulation-related withstand voltage level, μ represents the mean free path of the atmosphere gas, and L represents the creeping distance between the conductive member on the substrate 10 (10a) and the metal body 105.

V∝L/μ (Expression 3)

Thus, the withstand voltage level V is proportional to the inverse of the mean free path μ of the atmosphere gas. Accordingly, in addition to an increase in the creeping distance L because of the discharge-reducing portion 12, a decrease in the mean free path μ of the atmosphere gas can further improve the withstand voltage performance.

Therefore, in the case where helium is mixed as an atmosphere gas as described above, it is conceivable that, as the atmosphere gas of the light-emitting device 1 or 2, a gas having a mean free path less than the mean free path of helium is mixed in order to improve the withstand voltage performance.

For example, nitrogen has a mean free path less than the mean free path of helium under the same temperature and pressure. Thus, into the outer shell member of the lamp including the light-emitting device 1 or 2, a gas containing helium and nitrogen is included.

By doing so, in this lamp, not only an improvement in the heat radiation effect due to helium, but also an improvement in the withstand voltage performance due to nitrogen are expected.

The light-emitting device and the lamp according to implementations of the present invention have been described above based on Embodiments 1 and 2. However, the present invention is not limited to these descriptions. Without departing from the scope of the present invention, the present invention includes an embodiment obtained by making, to one of the above-described Embodiments 1 and 2, some modifications that are conceived by a person skilled in the art, or an embodiment obtained through combinations of the structural elements described above.

For example, in the light-emitting devices 1 and 2, the blue LED chip is adopted as the LED 20, and the yellow phosphor particles are adopted as a material for wavelength conversion from blue light to white light. However, the combination of the LED 20 and the phosphor particles is not limited to this combination.

For example, the light-emitting devices 1 and 2 may emit white light using the blue LED chip which emits blue light, and green phosphor particles and red phosphor particles which are excited by the blue light and thereby emit green light and red light, respectively.

Alternatively, for example, the light-emitting devices 1 and 2 may emit white light using an ultraviolet LED chip which emits ultraviolet light that is shorter in wavelength than blue light, and blue phosphor particles, green phosphor particles, and red phosphor particles which are mainly excited by the ultraviolet light and thereby emit blue light, red light, and green light.

The above has illustrated the LED as the semiconductor light-emitting element included in each of the light-emitting devices 1 and 2. However, the semiconductor light-emitting element included in each of the light-emitting devices 1 and 2 may be a semiconductor laser or an organic electro luminescence (EL).

### INDUSTRIAL APPLICABILITY

The present invention can be widely utilized, for example, as a mounting substrate for mounting a semiconductor light-emitting element, such as an LED, a light-emitting device which includes the semiconductor light-emitting element, and a lamp which includes the light-emitting device.

### REFERENCE SIGNS LIST

1,2 Light-emitting device
10, 10a Substrate
11, 11a Fitting portion
12 Discharge-reducing portion
12a Wall portion
12b Groove portion
13a First region
13b Second region
15 Electrode
18 Wiring
20 LED
50 Fitting hole
100 Lamp
101 Globe
102 Base
103 Outer case
103a First opening end
103b Second opening end
104 Metal clamp
105 Metal body
105 Concave portion
106 Inner case
107 Lighting circuit
161 First case part
161a First opening
162 Second case part
162b Second opening
162b Threaded portion
163 Resin cap
163a Protrusion
163b Through hole
171 Circuit element group
171a First capacitor element
171b Second capacitor element
171c Resistor element
171d Voltage converter element
171e Semiconductor element
172 Circuit board
173a, 173b Connector
180 Insulating ring

1.-13. (canceled)

14. A mounting substrate (i) having a mounting surface on which a semiconductor light-emitting element is mounted and (ii) to which a metal body is fitted, the mounting substrate comprising:
a conductive member provided on the mounting surface and electrically connected to the semiconductor light-emitting element;
a fitting portion to which the metal body is fitted; and
a discharge-reducing portion provided between the conductive member and the fitting portion and having a face tilted with respect to a surface of the mounting substrate, thereby increasing a creeping distance between the conductive member and the fitting portion compared to the case where the discharge-reducing portion is not provided,
wherein the discharge-reducing portion is a wall portion which protrudes from the surface of the mounting substrate and includes an insulating material, and
the wall portion has a light-transmitting property which allows transmission of light emitted from the semiconductor light-emitting element.

15. The mounting substrate according to claim 14,
wherein the wall portion is provided between the conductive member and an edge of the mounting surface, and a height of the wall portion measured from the mounting surface is lower than a height of the semiconductor light-emitting element measured from the mounting surface.

16. The mounting substrate according to claim 14,
wherein the wall portion includes the insulating material added to the surface of the mounting surface.

17. A mounting substrate (i) having a mounting surface on which a semiconductor light-emitting element is mounted and (ii) to which a metal body is fitted, the mounting substrate comprising:
the semiconductor light-emitting element;
a conductive member provided on the mounting surface and electrically connected to the semiconductor light-emitting element;
a fitting portion to which the metal body is fitted; and
a discharge-reducing portion provided between the conductive member and the fitting portion and having a face tilted with respect to a surface of the mounting substrate, thereby increasing a creeping distance between the conductive member and the fitting portion compared to the case where the discharge-reducing portion is not provided,
wherein the discharge-reducing portion is a groove portion recessed into the surface of the mounting substrate.

18. The mounting substrate according to claim 14,
wherein the mounting surface has: a first region including (i) a region in which the semiconductor light-emitting element is mounted and (ii) a region in which the conductive member is provided; and a second region outside the first region, and
the discharge-reducing portion is provided in the second region.

19. The mounting substrate according to claim 18,
wherein the discharge-reducing portion surrounds the first region.

20. The mounting substrate according to claim 14,
wherein the discharge-reducing portion includes: a first discharge-reducing portion which surrounds the conductive member; and a second discharge-reducing portion which surrounds the semiconductor light-emitting element.

21. The mounting substrate according to claim 14,
wherein the mounting surface is capable of accommodating two or more of the semiconductor light-emitting elements, and
the discharge-reducing portion includes a crossing portion which extends crosswise between the two semiconductor light-emitting elements.

22. A light-emitting device comprising
the mounting substrate according to claim 14, which includes the semiconductor light-emitting element mounted on the mounting substrate.

23. A lamp comprising:
the light-emitting device according to claim 22; and
the metal body fitted with the light-emitting device.

24. The lamp according to claim 23, further comprising
an outer shell member having a light-transmitting property and including a helium-containing gas, for covering the light-emitting device.

25. The mounting substrate according to claim 17,
wherein the mounting surface has: a first region including (i) a region in which the semiconductor light-emitting element is mounted and (ii) a region in which the conductive member is provided; and a second region outside the first region, and
the discharge-reducing portion is provided in the second region.

26. The mounting substrate according to claim 25,
wherein the discharge-reducing portion surrounds the first region.

27. The mounting substrate according to claim 17,
wherein the discharge-reducing portion includes: a first discharge-reducing portion which surrounds the conductive member; and a second discharge-reducing portion which surrounds the semiconductor light-emitting element.

28. The mounting substrate according to claim 17,
wherein the mounting surface is capable of accommodating two or more of the semiconductor light-emitting elements, and
the discharge-reducing portion includes a crossing portion which extends crosswise between the two semiconductor light-emitting elements.

29. A light-emitting device comprising
the mounting substrate according to claim 17, which includes the semiconductor light-emitting element mounted on the mounting substrate.

30. A lamp comprising:
the light-emitting device according to claim 29; and
the metal body fitted with the light-emitting device.

31. The lamp according to claim 30, further comprising
an outer shell member having a light-transmitting property and including a helium-containing gas, for covering the light-emitting device.
